(19) United States
(12) Patent Application Publication
(10) Pub. No.: US 2008/0083964 A1
(43) Pub. Date: Apr. 10, 2008

(54) Semiconductor image sensor die and production method thereof, semiconductor image sensor module, image sensor device, optical device element, and optical device module

(76) Inventors: Hiroaki Fujimoto, Osaka (JP); Masanori Minamio, Osaka (JP); Toshiyuki Fukuda, Kyoto (JP)

Correspondence Address: MCDERMOTT WILL & EMERY LLP, 600 13TH STREET, NW, WASHINGTON, DC, 20005-3096, US

(21) Appl. No.: 11/889,675

(22) Filed: Aug. 15, 2007

(30) Foreign Application Priority Data
Oct. 4, 2006 (JP) 2006-272831

(51) Int. Cl. H01L 31/0232; H01L 21/71

(52) U.S. Cl. 257/432; 257/81; 438/57; 257/E31.127; 257/E21.536

(57) ABSTRACT

A semiconductor image sensor die includes a substrate, an imaging area, a surrounding circuit area, a plurality of electrode portions, a translucent member, a transparent adhesive, and a bump. The imaging area, the surrounding circuit area, and the electrode portion are provided on an upper surface of the substrate. The surrounding circuit area is provided outside the imaging area. The electrode portion is provided outside the surrounding circuit area. The translucent member is adhered via the transparent adhesive to the imaging area, covering the imaging area. The bump is provided on a portion of the electrode portions. The surface of the bump includes an upper surface which is located higher than an upper surface of the transparent adhesive.

### BACKGROUND OF THE INVENTION

1. Field of the Invention

The present invention relates to a semiconductor image sensor die and a production method thereof, a semiconductor image sensor module, an image sensor device, an optical device element, and optical device module.

2. Description of the Related Art

In recent years, there is an increasing demand for high-density mounting of semiconductor apparatuses as electronic apparatuses become smaller, thinner, and lighter. In addition, the packing density of semiconductor elements is desired to be increased by the advance of microfabrication technology. To meet the demands, a technique (a so-called chip mounting technique) has been proposed in which a chip size package or a bare chip is directly mounted. There is a similar trend in optical devices, light emitting devices (e.g., surface-emitting lasers or LEDs (light emitting diodes)), light receiving elements (e.g., photodiodes), and semiconductor image sensor devicees, and various arrangements thereof have been proposed.

For example, in order to cause a semiconductor image sensor device to be thin and have low manufacturing cost, a technique has been proposed in which an adhesive having a low refractive index is used to attach a transparent plate directly onto a microlens in an imaging area of a semiconductor element (see, for example, Japanese Unexamined Patent Application Publication No. 2003-31782 (hereinafter referred to as Document 1)).

In this technique, a microlens is initially formed directly on a semiconductor element having an imaging area, and a transparent plate is then attached directly onto the microlens while maintaining the transparent plate in parallel with the imaging area. When the transparent plate is attached onto the microlens, a gap between the microlens and the transparent plate is filled with an adhesive having a low refractive index. Thereby, the electric characteristics and optical characteristics of the semiconductor image sensor device can be secured even when the environmental conditions for the semiconductor image sensor device vary, thereby making it possible to secure the reliability of the semiconductor image sensor device.

In most cases, a semiconductor image sensor die is provided in a hollow package. In this case, a transparent plate (a part of the hollow package) is provided separately from a microlens, which causes the semiconductor image sensor device to be thick. In contrast, in the semiconductor image sensor device disclosed in Document 1, a semiconductor image sensor die is protected by attaching a transparent plate directly onto a microlens on a semiconductor image sensor die, so that the semiconductor image sensor die does not need to be provided in the hollow package. In addition, since the semiconductor image sensor die is not provided in the hollow package, the transparent plate does not need to be provided separately from the microlens, thereby making it possible to reduce the thickness of the semiconductor image sensor device. Therefore, the technique of Document 1 can be used to achieve a low-cost and thin semiconductor image sensor device.

However, when the technique of Document 1 is used, the adhesive for attaching the transparent plate onto the microlens may flow out of the imaging area of the semiconductor image sensor die and adhere onto a bonding pad. If the adhesive adheres onto the bonding pad, a wire may not be stably adhered onto the bonding pad during wire bonding.

To solve such a problem, a technique has been disclosed in which the bonding pad is covered with a resist film before the adhesive is provided on the microlens, and therefore, even when the adhesive flows out of the imaging area, the adhesive does not adhere onto the bonding pad (see, for example, Japanese Unexamined Patent Application Publication No. 56-18477 (hereinafter referred to as Document 2)). In this method, even when the adhesive flows out of the imaging area, the resist film protects the bonding pad. Therefore, if wire bonding is performed after the adhesive is dried and the resist film is then removed, a wire can be stably adhered onto the bonding pad.

Also, a semiconductor apparatus having a number of terminals and a production method thereof have been proposed in which bonding pads are arranged in a staggered array (alternatively arranged in a staggered manner) so as to reduce the size and thickness of the semiconductor apparatus (see, for example, Japanese Unexamined Patent Application Publication No. 2002-43357 (hereinafter referred to as Document 3)). In this method, a semiconductor chip is provided on an insulating substrate, the bonding pads are arranged in a stagger pattern on a major surface of the semiconductor chip, and a multilayer stud bump in which a plurality of stud bumps are stacked is provided on inner pads (bonding pads located farther inside the semiconductor chip).

In the semiconductor apparatus disclosed in Document 3, a land is provided on the insulating substrate, and the land and the bonding pad are connected to each other via a conductive wire. In this case, the start end of the conductive wire is connected to the land while the terminal end of the conductive wire is connected to the bonding pad. Therefore, the height of a wire loop at the start end of the conductive wire can be suppressed to a low level. Also, since the multilayer stud bump is provided at the inner pad, the terminal end of the conductive wire connected to the inner pad is provided higher than the terminal end of the conductive wire connected to the outer pad. Therefore, even when adjacent conductive wires have a small gap therebetween, it is possible to suppress the conductive wires from contacting each other. Thereby, a plurality of conductive wires can be arranged in a staggered array in a three-dimensional manner and with high density.

### SUMMARY OF THE INVENTION

A semiconductor image sensor die according to the present invention comprises a substrate. An imaging area is provided in a portion of an upper surface of the substrate. A surrounding circuit area is provided outside the imaging area of the upper surface of the substrate. A plurality of electrode portions provided outside the surrounding circuit area of the upper surface of the substrate. A translucent member is provided, covering the imaging area. The translucent member is adhered via a transparent adhesive to the substrate. A bump is provided on at least one of the electrode portions. The surface of the bump includes an upper surface provided higher than an upper surface of the transparent adhesive provided on the surrounding circuit area.

Thus, the translucent member is adhered via the adhesive to the substrate, thereby making it possible to cause the semiconductor image sensor die to be thin. Also, the surface of the bump includes the upper surface, thereby making it possible to electrically connect the semiconductor image sensor die via the upper surface to a wiring substrate or the like.

A semiconductor image sensor device and a semiconductor imaging module according to the present invention comprises the semiconductor image sensor die of the present invention.

An optical device element according to the present invention has a configuration similar to that of the semiconductor image sensor die of the present invention, except that a light receiving and emitting area is provided on the substrate instead of the imaging area. Also, an optical device module according to the present invention comprises the optical device element of the present invention.

### BRIEF DESCRIPTION OF THE DRAWINGS

FIG. 1 is a cross-sectional view schematically showing a configuration of a semiconductor image sensor die according to a first embodiment of the present invention.

FIG. 2A is a plan view of a semiconductor wafer on which a semiconductor element is formed which is included in the semiconductor image sensor die of first embodiment of the present invention.

FIG. 2B is a plan view of each semiconductor element.

FIG. 2C is a cross-sectional view, taken along line IIC-IIC of FIG. 2B.

FIG. 3A to FIG. 3E are cross-sectional views showing a method for producing the semiconductor image sensor die of the first embodiment of the present invention.

FIG. 4 is a cross-sectional view showing a configuration of a semiconductor image sensor device according to the first embodiment of the present invention.

FIGS. 5A to 5D are cross-sectional views showing a method for producing the semiconductor image sensor device of the first embodiment of the present invention.

FIG. 6 is a cross-sectional view showing a configuration of a semiconductor image sensor die according to a variation of this embodiment.

FIG. 7A is a cross-sectional view showing a configuration of a semiconductor image sensor die according to a second embodiment of the present invention.

FIG. 7B is a cross-sectional view showing a configuration of a first semiconductor image sensor device according to the second embodiment of the present invention.

FIG. 7C is a cross-sectional view showing a configuration of a second semiconductor image sensor device according to the second embodiment of the present invention.

FIG. 8 is a cross-sectional view showing a configuration of a third semiconductor image sensor device according to the second embodiment of the present invention.

FIG. 9A is a plan view showing a semiconductor image sensor die according to a third embodiment of the present invention.

FIG. 9B is a cross-sectional view, taken along line IXB-IXB in FIG. 9A.

FIG. 9C is a cross-sectional view, taken along line IXC-IXC in FIG. 9A.

FIG. 10A is a cross-sectional view showing a configuration of a first semiconductor imaging module according to a fourth embodiment of the present invention.

FIG. 10B is a cross-sectional view showing a configuration of a second semiconductor imaging module according to the fourth embodiment of the present invention.

FIG. 11A is a cross-sectional view showing a configuration of a first semiconductor imaging module according to a fifth embodiment of the present invention.

FIG. 11B is a cross-sectional view showing a configuration of a second semiconductor imaging module according to the fifth embodiment of the present invention.

FIG. 12 is a cross-sectional view showing a configuration of a semiconductor image sensor die according to a sixth embodiment of the present invention.

### DETAILED DESCRIPTION OF THE PREFERRED EMBODIMENTS

In the technique disclosed in Document 2, although the thickness of the semiconductor image sensor device can be reduced, the step of forming a resist film and the step of removing the resist film are required. Therefore, the number of steps for manufacture of the semiconductor image sensor device increases, disadvantageously leading to an increase in the manufacturing cost and manufacturing time of the semiconductor image sensor device, i.e., a reduction in the productivity of the semiconductor image sensor device. In addition, when the resist film is removed, a portion of the cured adhesive may be peeled off. If peeled adhesive pieces remain on a semiconductor element, the electric characteristics, optical characteristics or reliability of the semiconductor image sensor device is likely to be decreased.

In the technique disclosed in Document 3, conductive wires can be mounted with high density. However, since the multilayer stud bump is provided on the inner bonding pad, it is difficult to reduce the thickness of the semiconductor apparatus.

The present invention can provide a semiconductor image sensor die and a production method thereof, a semiconductor image sensor device, and a semiconductor imaging module which have a thin thickness, excellent reliability, and high productivity. In addition to the semiconductor image sensor die, the present invention can provide an optical device element and an optical device module which have a thin thickness, excellent reliability, and high productivity.

Hereinafter, semiconductor apparatuses according to embodiments of the present invention will be described with reference to the accompanying drawings. Although a semiconductor image sensor die, a semiconductor image sensor device, and a semiconductor image sensor module will be described as examples, the present invention is similarly applicable to other optical devices (a light receiving element or a light emitting device) in addition to the semiconductor image sensor die. A photodiode may be an example of the light receiving element, and a surface-emitting laser, an LED or the like may be an example of the light emitting device.

Substantially the same parts are hereinafter indicated by the same reference numerals and will not be repeatedly described. Parts are schematically illustrated for the sake of easy understanding. The shapes, the number and the like of parts are not limited to those shown in the drawings.

### First Embodiment

In a first embodiment, a configuration and a production method of the semiconductor image sensor die, and a configuration and a production method of the semiconductor image sensor device will be successively described.

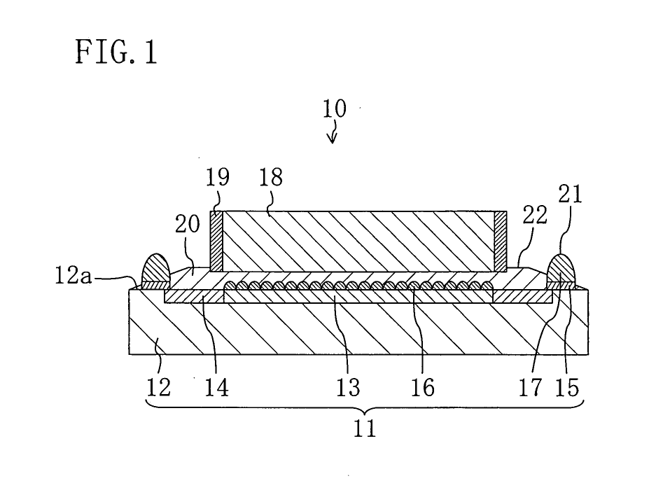

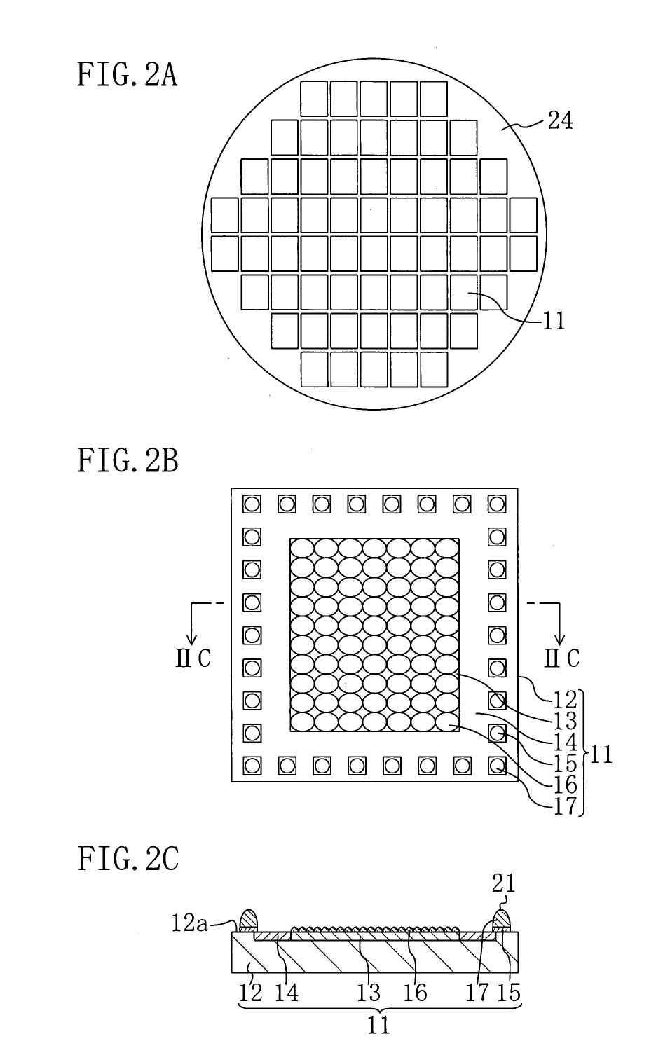

FIG. 1 is a cross-sectional view schematically showing the configuration of the semiconductor image sensor die 10 of this embodiment. FIG. 2A is a top view of a semiconductor wafer 24. FIG. 2B is a top view of each semiconductor element 11. FIG. 2C is a cross-sectional view, taken along line IIC-IIC of FIG. 2B.

The semiconductor image sensor die 10 of this embodiment comprises the semiconductor element 11 of FIGS. 2B and 2C, a translucent member 18, and a transparent adhesive 20.

The semiconductor element 11 is preferably produced by dicing the semiconductor wafer 24 of FIG. 2A, and has a substrate 12. An imaging area 13 and a peripheral circuit area 14 are provided on an upper surface 12a of the substrate 12. On the upper surface 12a of the substrate 12, the peripheral circuit area 14 is provided outside the imaging area 13, contacting the imaging area 13.

The imaging area 13 is preferably formed of a plurality of pixels each of which comprises a photodiode. A microlens 16 is formed on each pixel. Each microlens 16 is preferably formed of a transparent acrylic resin or the like. The translucent member 18 is adhered to the microlenses 16, 16, . . . via the transparent adhesive 20. A light shielding film 19 is provided on a side surface of the translucent member 18. The light shielding film 19 is preferably formed of a metal or a resin having a light shielding property. As a method for forming the light shielding film 19, for example, a resist film is initially formed, exposing the side surface of the translucent member 18, a metal film is then formed on the translucent member 18 by a deposition technique or the like, and the resist film is then removed, though the present invention is not limited to this.

A plurality of electrode portions 15, 15, . . . are provided outside the peripheral circuit area 14 on the upper surface 12a of the substrate 12. Bumps 17 are provided on a portion of the electrode portions 15, 15, . . . A portion (upper surface 21) of a surface of the bump 17 is located higher than an upper surface 22 of the transparent adhesive 20. In other words, the upper surface 21 is exposed from the transparent adhesive 20, and is electrically connected to an electrode terminal or the like of a package or a mounting substrate as described below. Thus, since the upper surface 21 is present in the surface of the bump 17, the upper surface 21 can be electrically connected to the electrode terminal of the package or the like using a conductive wire or the like. Alternatively, the upper surface 21 can be directly connected to the electrode terminal without via a conductive wire or the like. Further, if the upper surface 21 is planarized, the upper surface 21 can be easily connected to the electrode terminal of the package or the like.

As described above, since the upper surface 21 is present in the surface of the bump 17, it is possible to prevent the whole bump 17 from being buried in the transparent adhesive 20. Therefore, the semiconductor image sensor die 10 of this embodiment can be electrically connected to a package or the like via the bump 17 (specifically, the upper surface 21 of the bump 17).

Also, the translucent member 18 protects the semiconductor element 11 (particularly, the imaging area 13). Therefore, even if dust (cuttings) occurs in a machining step, such as a scribing step, a dicing step or the like, after the microlens 16 is adhered to the translucent member 18, it is possible to prevent the dust from adhering onto the imaging area 13. Therefore, a degradation in optical characteristics of the semiconductor image sensor die 10 can be suppressed.

In addition, the side surface of the translucent member 18 is covered with the light shielding film 19, thereby making it possible to prevent stray light from entering the imaging area 13. For example, when light entering the major surface of the translucent member 18 is erroneously reflected on the side surface of the translucent member 18, the reflected light is absorbed or scattered by the light shielding film 19, so that the reflected light can be suppressed from entering the imaging area 13, or the intensity of the reflected light entering the imaging area 13 can be reduced. Also, when the semiconductor image sensor die 10 is electrically connected to a package or the like using a conductive wire, light is also scattered or reflected on a surface of the conductive wire, but the scattered light or the reflected light can be suppressed from entering the imaging area 13. Thereby, it is possible to prevent the occurrence of a flare, a smear or the like in an image signal.

Also, the translucent member 18 is adhered via the transparent adhesive 20 onto the microlens 16, thereby making it possible to obtain the semiconductor image sensor die 10 which is thin, small, and highly reliable.

Note that, in this embodiment, the substrate 12 is preferably formed of silicon, germanium, a compound semiconductor material (e.g., GaAs, InP, GaN, SiC, etc.), or the like. The bump 17 is preferably formed of aluminum, copper, gold or the like, which is a conductive material which does not chemically react with the transparent adhesive 20. The translucent member 18 is preferably formed of, for example, Tefles (registered trademark) glass, Pyrex (registered trademark) glass, quartz, an acrylic resin, a polyimide resin, an epoxy resin or the like, and can be produced by shaping the material into a sheet. The transparent adhesive 20 may be formed of a UV-curable resin or a thermosetting resin, such as, for example, an acrylic resin, a polyimide resin, an epoxy resin or the like.

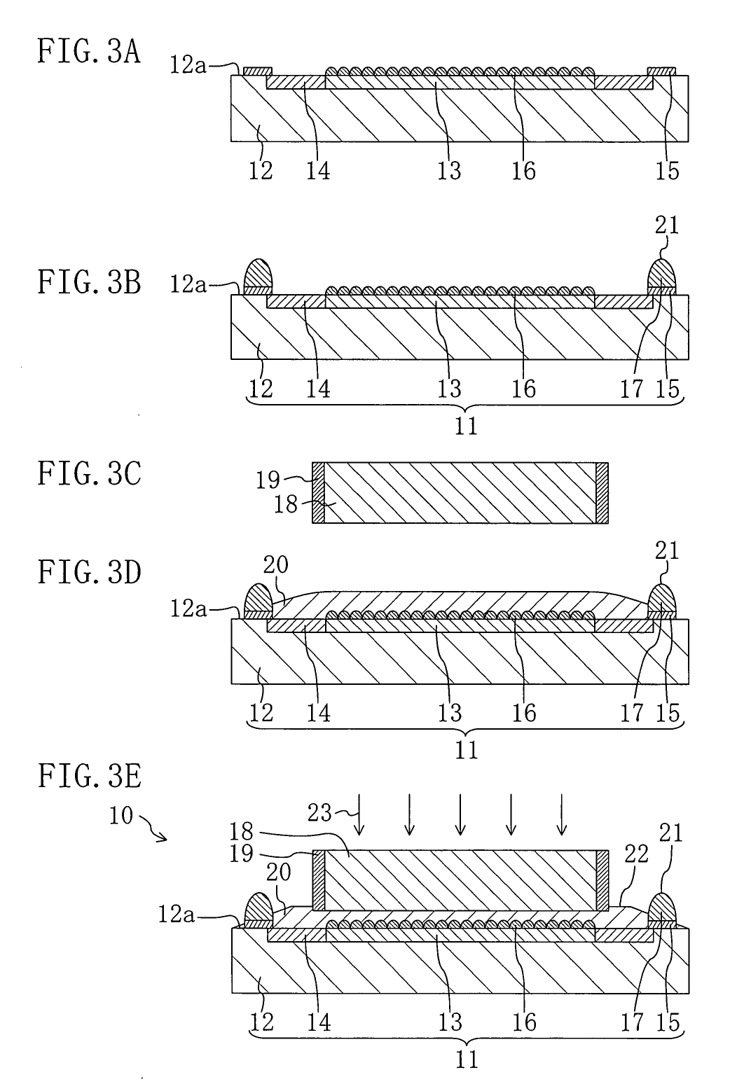

FIGS. 3A to 3E are cross-sectional views showing steps of producing the semiconductor image sensor die 10 of this embodiment.

Initially, the semiconductor wafer 24 of FIG. 2A is prepared. In the semiconductor wafer 24, the semiconductor elements 11, 11, . . . are arranged in an array with a predetermined pitch. As described above, each semiconductor element 11 has the substrate 12, the imaging area 13, the peripheral circuit area 14, the electrode portions 15, 15, . . . , and an array of the microlenses 16. Also, if the semiconductor wafer 24 has a thickness of 150 μm or more and 1000 μm or less, more preferably 300 μm or more and 500 μm or less, the productivity of the semiconductor image sensor die 10 can be preferably improved and the manufacturing cost of the semiconductor image sensor die 10 can be preferably suppressed.

Next, as shown in FIG. 3B, the bumps 17 are provided on a portion of the electrode portions 15, 15, . . . For example, the bump 17 can be formed using a conductive wire, though the present invention is not limited to this. Also, the upper surface 21 of the bump 17 is preferably suppressed using a metal plate or the like after the bump 17 is formed. Thereby, the height of the upper surface 21 of the bump 17 can be caused to be uniform and even, thereby making it possible to easily connect a conductive wire 35 to the upper surface 21.

Following this, as shown in FIG. 3C, the translucent member 18 on whose side surface the light shielding film 19 is formed is prepared. In this case, if the translucent member 18 has a thickness of 150 μm or more and 500 μm or less, more preferably 200 μm or more and 400 μm or less, the productivity of the semiconductor image sensor die 10 can be preferably improved and the manufacturing cost of the semiconductor image sensor die 10 can be preferably suppressed.

Following this, as shown in FIG. 3D, the transparent adhesive 20 is applied to cover the microlenses 16 and a portion of a surrounding of the microlenses 16. The transparent adhesive 20 is preferably a UV-curable resin, which is applied by a drawing method, a printing method, a stamping method, or the like. In this case, the upper surface 21 of the bump 17 is preferably exposed from the transparent adhesive 20.

Following this, as shown in FIG. 3E, the translucent member 18 is positioned over the imaging area 13. Thereafter, a pressure is applied to an upper surface of the translucent member 18 while the upper surface of the translucent member 18 is maintained in parallel with the imaging area 13. The translucent member 18 is irradiated with ultraviolet light from the upper surface thereof as indicated by arrows 23 to cure the transparent adhesive 20. Thereby, the imaging area 13 and the translucent member 18 are adhered to each other via the transparent adhesive 20.

Finally, the semiconductor wafer 24 is diced. Thereby, the semiconductor image sensor die 10 of FIG. 1 can be obtained.

When such a method is used to produce the semiconductor image sensor die 10, the translucent member 18 is adhered via the transparent adhesive 20 onto the microlens 16, the semiconductor image sensor die 10 can be caused to be thin. Also, the transparent adhesive 20 is provided, exposing the upper surface 21 of the bump 17, thereby making it possible to prevent the transparent adhesive 20 from adhering to the upper surface 21 of the bump 17. Therefore, when a conductive wire is used to electrically connect the semiconductor image sensor die 10 to a package or the like, the conductive wire can be firmly fixed to the upper surface 21. Thereby, a reduction in the mass productivity of the semiconductor image sensor die 10 can be suppressed.

Also, since the translucent member 18 is adhered onto the microlens 16 before the semiconductor wafer 24 is diced, the microlens 16 is not likely to be damaged during dicing, and also, dust (cuttings) and the like can be prevented from adhering onto the microlens 16. Therefore, the yield of the semiconductor image sensor die 10 can be improved. Further, if the surface of the translucent member 18 is covered with a resin film or the like during dicing or the like, dicing can be performed without damaging the surface of the translucent member 18. Also, even when dust adheres to the surface of the resin film during dicing, the dust can be suppressed from adhering onto the translucent member 18 by removing the resin film after dicing.

Although the semiconductor image sensor dies 10, 10, . . . are formed on the semiconductor wafer 24 before the semiconductor wafer 24 is diced in this embodiment, a semiconductor wafer may be initially diced into a plurality of the substrates 12, and each substrate 12 may be used to produce the semiconductor image sensor die 10.

Also, an image test or an electric characteristics test may be performed with respect to the semiconductor element 11 before the translucent member 18 is provided, and the translucent member 18 may be provided on only a semiconductor element(s) 11, which has been determined to be a non-defective product.

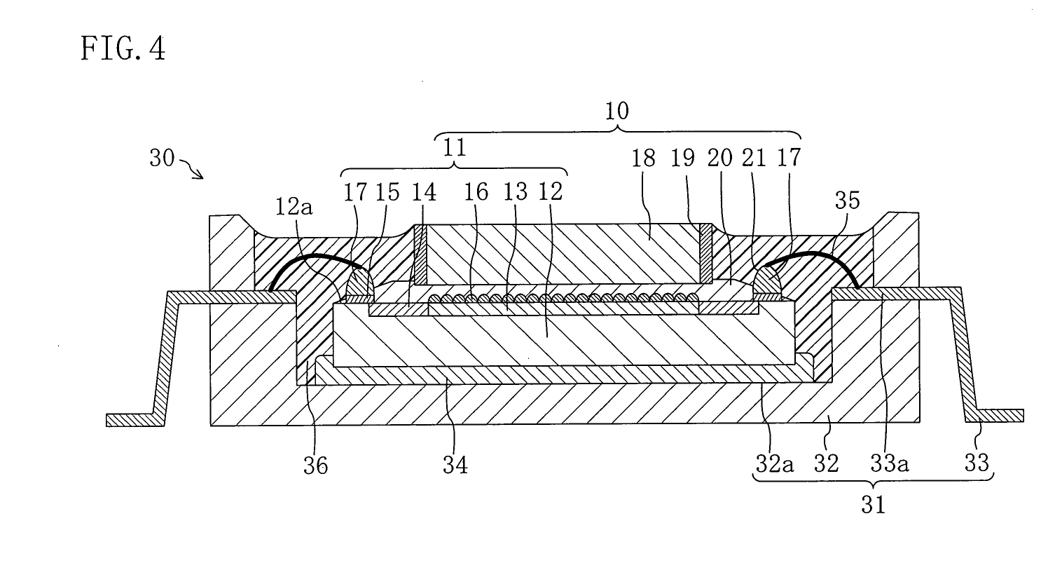

FIG. 4 is a cross-sectional view showing a configuration of a semiconductor image sensor device 30 according to this embodiment.

The semiconductor image sensor device 30 of this embodiment comprises the semiconductor image sensor die 10 and a package 31.

The package 31 has a package substrate 32. A cavity is formed in the package substrate 32. An attachment portion 32a is provided on a bottom surface of the cavity, and the semiconductor image sensor die 10 is fixed to the attachment portion 32a via a fixing agent 34. Preferable examples of the fixing agent 34 include, but are not limited to, an epoxy resin, a polyimide resin, and the like. Also, an internal wall surface of the cavity is subjected to satin finish, thereby preventing reflection on the internal wall surface of the cavity.

Also, the package 31 is provided with a terminal pin 33. The terminal pin 33 is provided with a connection portion 33a. The connection portion 33a is connected via the conductive wire 35 to the upper surface 21 of the bump 17, whereby the semiconductor image sensor die 10 and the terminal pin 33 can be electrically connected to each other. Here, the start end of the conductive wire 35 is preferably connected to the connection portion 33a, while the terminal end of the conductive wire 35 is preferably connected to the upper surface 21. Thereby, as shown in FIG. 4, the loop height of the conductive wire 35 can be suppressed to a low level, thereby making it possible to provide the conductive wire 35 at a position lower than the upper surface of the translucent member 18. Thereby, the semiconductor image sensor device 30 can be caused to be thin.

The cavity of the package substrate 32 is filled with a sealing resin 36. The sealing resin 36 is preferably a resin having a light shielding property, such as, for example, an epoxy resin, a polyimide resin or the like, which seals the semiconductor image sensor die 10 and the conductive wire 35.

As described above, the semiconductor image sensor device 30 comprises the semiconductor image sensor die 10. Therefore, in the semiconductor image sensor device 30, the occurrence of a flare, a smear or the like can be prevented, thereby making it possible to achieve a thin and small semiconductor image sensor device.

Although the package 31 provided with the terminal pin 33 is used as a package in this embodiment, a package without a terminal pin may be used.

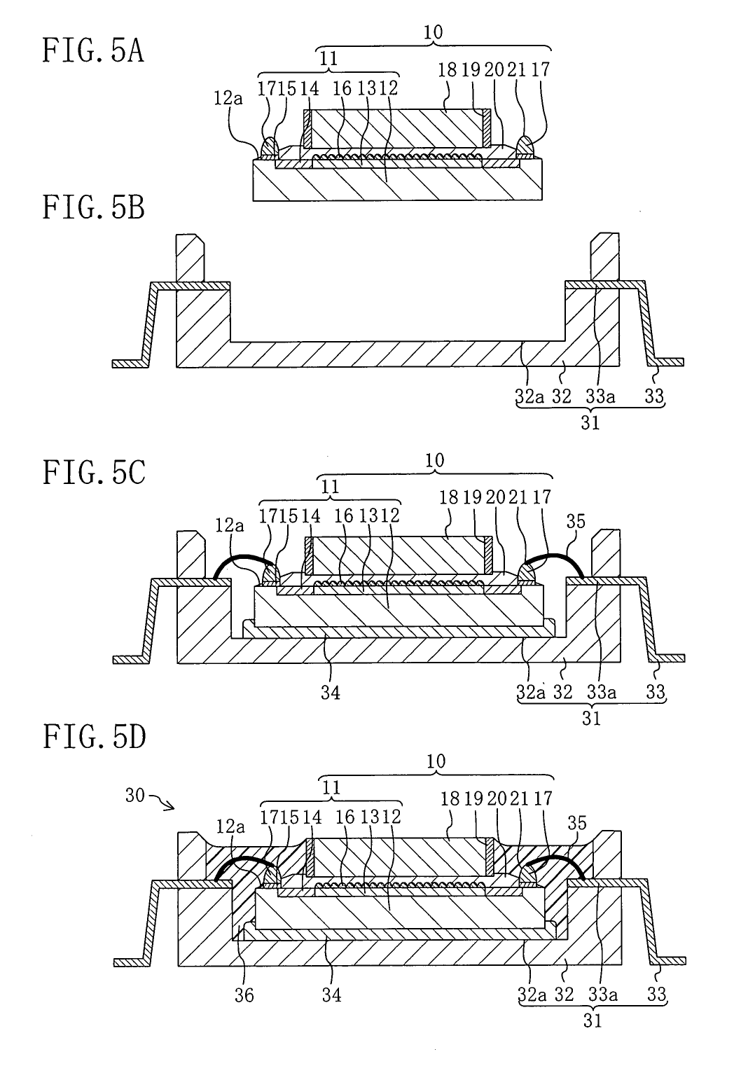

FIGS. 5A to 5D are cross-sectional views showing steps of producing the semiconductor image sensor device 30 of this embodiment.

Initially, the semiconductor image sensor die 10 of FIG. 5A is prepared.

Next, the package 31 of FIG. 5B is prepared. The package 31 is provided with the package substrate 32 and the terminal pin 33 as described above. A cavity is formed in the package substrate 32. In this case, in order to prevent stray light from entering the imaging area 13, an internal wall surface of the cavity is preferably caused to be rough, and a depth of the cavity is preferably caused to be greater than or equal to a thickness of the semiconductor image sensor die 10.

Following this, the fixing agent 34 is applied to the attachment portion 32a of the package substrate 32. In this case, an application method may be, but is not limited to, a drawing method. Thereafter, the semiconductor image sensor die 10 is adhered to the attachment portion 32a while maintaining the major surface of the semiconductor image sensor die 10 in parallel with the attachment portion 32a. The upper surface 21 of the bump 17 is then connected to the connection portion 33a using the conductive wire 35. Thereby, as shown in FIG. 5C, the semiconductor image sensor die 10 can be electrically connected to the terminal pin 33 of the package 31.

Next, as shown in FIG. 5D, the cavity of the package 31 is filled with the sealing resin 36 having a light shielding property. In this case, the sealing resin 36 is inserted into a gap between the semiconductor image sensor die 10 and the internal wall surface of the cavity of the package substrate 32 so that the conductive wire 35 is buried. Thereafter, the package 31 is heated to cure the sealing resin 36. As a result, the semiconductor image sensor device 30 of this embodiment can be obtained.

In the semiconductor image sensor device 30 which is produced in such a method, the light shielding film 19 is provided on the side surface of the translucent member 18, and a resin having a light shielding property is used as the sealing resin 36. Therefore, stray light can be prevented from entering the imaging area 13. As a result, it is possible to prevent the occurrence of optical noise, such as a flare, a smear or the like, in the semiconductor image sensor device 30. Thus, the semiconductor image sensor device 30 having excellent optical characteristics can be provided.

Note that the sealing resin is not limited to a resin having a light shielding property and may be a transparent resin. Even when a transparent resin is used as the sealing resin, since the light shielding member is formed on the side surface of the translucent member 18, stray light can be prevented from entering the imaging area 13. In this arrangement, the upper surface of the transparent adhesive is not shielded from light, so that stray light may enter the imaging area from the upper surface of the transparent adhesive 20. Nevertheless, since the thickness of the transparent adhesive 20 is small, it is not often that the optical performance of the semiconductor image sensor device is reduced.

(First Variation)

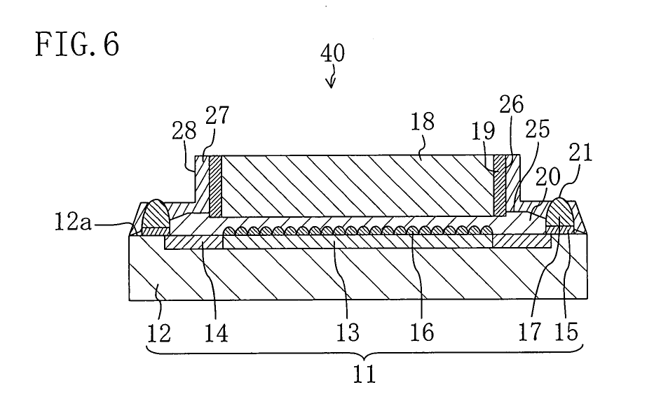

FIG. 6 is a diagram showing a configuration of a semiconductor image sensor die 40 according to a first variation of this embodiment. The semiconductor image sensor die 40 of FIG. 6 is provided with a light shielding member 27. The light shielding member 27 covers the side surface of the translucent member 18, and covers an upper surface 25 of the transparent adhesive 20 while exposing the upper surface 21 of the bump 17. Thereby, in the semiconductor image sensor die 40 of this variation, stray light can be further suppressed from entering the imaging area 13 than in the semiconductor image sensor die 10 of FIG. 1.

Note that a production method of the semiconductor image sensor die 40 of this variation is the same as the production method of the semiconductor image sensor die 10 of the first embodiment, except that a step of providing the light shielding member 27 (step (d)) is added. In the step of providing the light shielding member 27, the light shielding member 27 is provided, covering the upper surface 25 of the transparent adhesive 20 and the side surface (specifically, the light shielding film 19) of the translucent member 18. In this case, the light shielding member 27 is preferably provided, exposing the upper surface 21 of the bump 17.

By introducing the semiconductor image sensor die 40 into the cavity of the package substrate 32 of the package 31 of FIG. 5B, a semiconductor image sensor device can be produced. In such a semiconductor image sensor device, stray light can be further suppressed from entering the imaging area 13 than in the semiconductor image sensor device 30 of this embodiment, so that the occurrence of optical noise, such s a flare, a smear or the like, can be further prevented.

### Second Embodiment

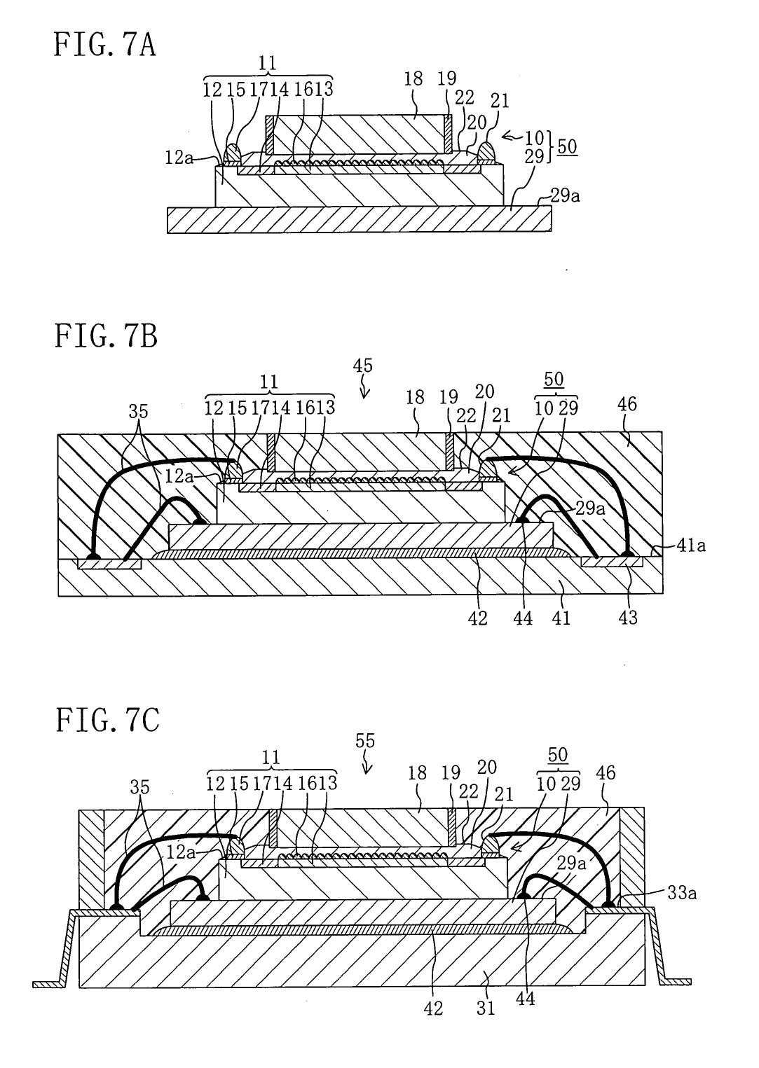

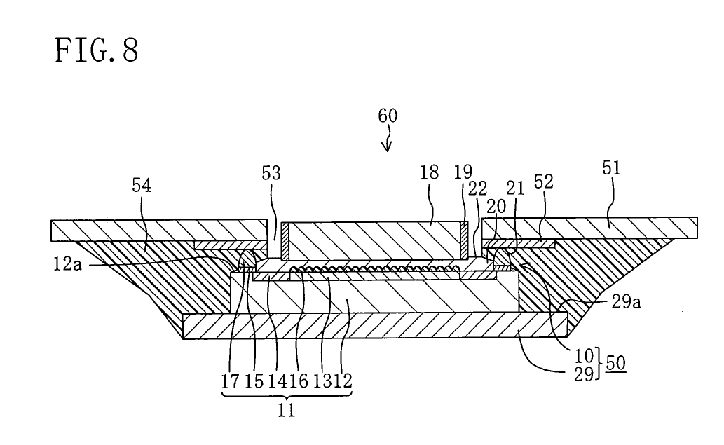

A second embodiment is different from the first embodiment in the configuration of the semiconductor image sensor die. FIG. 7A is a cross-sectional view showing a configuration of a semiconductor image sensor die according to this embodiment. FIGS. 7B, 7C and 8 are cross-sectional views showing configurations of first, second and third semiconductor image sensor devicees according to this embodiment.

As shown in FIG. 7A, the semiconductor image sensor die 50 of this embodiment comprises the semiconductor image sensor die 10 of the first embodiment and a semiconductor integrated element 29. The semiconductor image sensor die 10 is adhered onto a major surface 29a of the semiconductor integrated element 29 via an insulating adhesive (not shown) or the like. The semiconductor integrated element 29 is an integrated element, such as, for example, a digital signal processor (DSP) or the like, so that the semiconductor image sensor die 50 has higher performance than that of the semiconductor image sensor die 10 of the first embodiment.

As shown in FIG. 7B, the first semiconductor image sensor device 45 of this embodiment comprises the semiconductor image sensor die 50 and a wiring substrate 41. The semiconductor image sensor die 50 is adhered via a fixing agent 42 to a major surface 41a to the wiring substrate 41 and is sealed with a sealing resin 46. An electrode terminal 43 is provided on the major surface 41a of the wiring substrate 41. The electrode terminal 43 is connected via the conductive wire 35 to the upper surface 21 of the bump 17 of the semiconductor image sensor die 10 and an electrode terminal 44 of the semiconductor integrated element 29. The conductive wire 35 is sealed with the sealing resin 46. Here, when the start end of the conductive wire 35 is connected to the electrode terminal 43 while the terminal end of the conductive wire 35 is connected to the bump 17, the semiconductor image sensor device 45 can be caused to be thin.

Such a semiconductor image sensor device 45 is produced as follows. Initially, the semiconductor image sensor die 50 of FIG. 7A is prepared. Next, the semiconductor image sensor die 50 is adhered via the fixing agent 42 to the major surface 41a of the wiring substrate 41. Following this, the conductive wire 35 is used to connect the electrode terminal 43 of the wiring substrate 41 to the bump 17 of the semiconductor image sensor die 10 and the electrode terminal 44 of the semiconductor integrated element 29. Thereafter, the sealing resin 46 is provided on the major surface 41a of the wiring substrate 41 to seal the semiconductor image sensor die 50 and the conductive wire 35. Thereby, the semiconductor image sensor device 45 can be caused to be thin and small.

As shown in FIG. 7C, the second semiconductor image sensor device 55 of this embodiment comprises the package 31 of the first embodiment instead of the wiring substrate 41 of FIG. 7B. In the semiconductor image sensor device 55, the semiconductor image sensor die 50 is adhered via the fixing agent 42 to the attachment portion 32a of the package substrate 32 of the package 31 and is sealed with the sealing resin 46. The package 31 is provided with the terminal pin 33 as described above. The connection portion 33a of the terminal pin 33 is connected via the conductive wire 35 to the upper surface 21 of the bump 17 of the semiconductor image sensor die 10 and an electrode portion 44 of the semiconductor integrated element 29. In this case, regarding the conductive wire 35 connecting the bump 17 and the connection portion 33a, preferably, the start end is connected to the connection portion 33a while the terminal end is connected to the bump 17. Regarding the conductive wire 35 connecting the electrode portion 44 and the connection portion 33a, preferably, the start end is connected to the electrode portion 44 while the terminal end is connected to the connection portion 33a. Thereby, the second semiconductor image sensor device 55 can be caused to be thin. Also, the cavity is filled with the sealing resin 46, so that the semiconductor image sensor die 50 and the conductive wire 35 are sealed with the sealing resin 46.

Such a semiconductor image sensor device 55 is produced by a method which is substantially the same as that for the semiconductor image sensor device 30 of the first embodiment.

As shown in FIG. 8, the third semiconductor image sensor device 60 of this embodiment comprises a mounting substrate (flexible mounting substrate) 51 instead of the wiring substrate 41 of FIG. 7B. In the mounting substrate 51, a through hole 53 is formed, and the translucent member 18 is housed in the through hole 53. Therefore, the through hole 53 preferably has an opening which is larger than that the upper surface of the translucent member 18. An electrode terminal 52 is formed around the opening of the through hole 53. The upper surface 21 of the bump 17 of the semiconductor image sensor die 10 contacts the electrode terminal 52. In other words, in the semiconductor image sensor device 60, the semiconductor image sensor die 50 is electrically connected to the mounting substrate 51 without via a conductive wire. Also, a sealing resin 54 is provided between the semiconductor integrated element 29 and the mounting substrate 51. The sealing resin 54 seals and fixes the semiconductor image sensor die 50 to the mounting substrate 51.

As described above, in the semiconductor image sensor device 60, as is different from the semiconductor image sensor devicees 45 and 55, the translucent member 18 is housed in the mounting substrate 51, thereby making it possible to cause the semiconductor image sensor device to be small and thin. Also, in the semiconductor image sensor device 60, the semiconductor image sensor die 50 is electrically connected to the mounting substrate 51 without via a conductive wire, thereby making it possible to prevent the occurrence of reflected light or scattered light on a surface of a conductive wire. Therefore, the optical performance of the semiconductor image sensor device 60 can be improved.

Although the electrode terminal is assumed to be provided only on one of the major surfaces of the wiring substrate or the mounting substrate in this embodiment, the electrode terminal may be provided both the major surfaces of the wiring substrate or the mounting substrate. If the electrode terminal is provided both the major surfaces of the wiring substrate or the mounting substrate, a semiconductor image sensor die can be provided on both the major surfaces of the wiring substrate or the mounting substrate, thereby making it possible to improve the performance of the semiconductor image sensor device.

Note that the semiconductor image sensor devicees 45, 55 and 60 may each be formed using the semiconductor image sensor die 10 instead of the semiconductor image sensor die 50.

### Third Embodiment

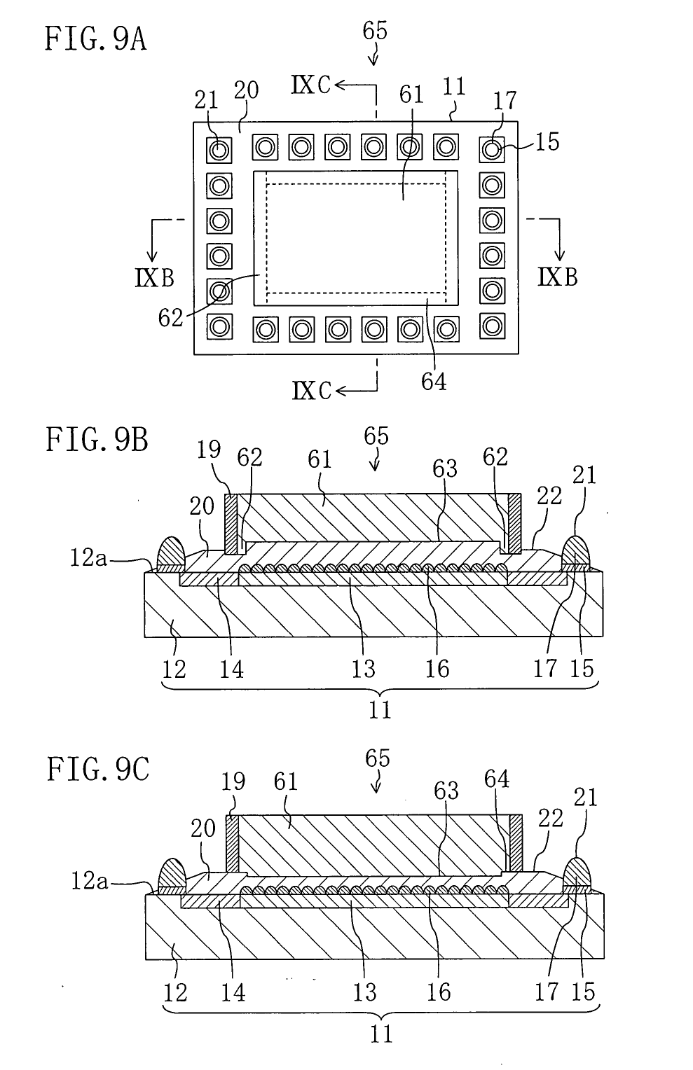

A third embodiment is different from the first and second embodiments in the shape of the translucent member. FIG. 9A is a plan view showing a semiconductor image sensor die 65 according to this embodiment. FIG. 9B is a cross-sectional view, taken along line IXB-IXB in FIG. 9A. FIG. 9C is a cross-sectional view, taken along line IXC-IXC in FIG. 9A.

The semiconductor image sensor die 65 comprises the semiconductor element 11 and a translucent member 61. The translucent member 61 is adhered via the transparent adhesive 20 to the microlens 16 of the semiconductor element 11. The translucent member 61 has a lower surface 63 which is not even. Convex portions 62 and concave portions 64 are formed in an area surrounding the lower surface 63.

Specifically, the convex portions 62 and 62 are provided along two opposed sides of the four sides of the lower surface (a surface to be adhered to the microlens 16) 63 of the translucent member 61, while the concave portions 64 and 64 are provided along two sides along which the convex portions 62 are not provided of the four sides of the lower surface 63. Each convex portion 62 is formed, protruding above a center area of the lower surface 63, while each concave portion 64 is formed and dented below the center area of the lower surface 63.

By providing the convex portions 62 and 62 in the lower surface 63 of the translucent member 61 in this manner, the melted transparent adhesive 20 is prevented from flowing farther outside than the convex portions 62 and 62. Therefore, the amount of the transparent adhesive 20 in a portion between the convex portions 62 and 62 and the electrode portion 15 can be caused to be smaller than the amount of the transparent adhesive 20 in the other portions. Thereby, the height of the surface 22 of the transparent adhesive 20 in the portion between the convex portions 62 and 62 and the electrode portion 15 can be caused to be lower than the height of the surface 22 of the transparent adhesive 20 of the other portions. In other words, by providing the convex portions 62 and 62 in the lower surface 63 of the translucent member 61, the upper surface 21 of the bump 17 provided along a longitudinal direction of the convex portion 62 can be easily exposed from the transparent adhesive 20. Therefore, both when the upper surface 21 of the bump 17 is connected to another electrode terminal via a conductive wire and when the upper surface 21 of the bump 17 is directly connected to another electrode terminal without via a conductive wire, electrical connection can be relatively easily and certainly achieved. Also, in view of this, the bump 17 is preferably provided on each electrode portion (electrode portions arranged in the length direction in FIG. 9A) 15 arranged along the longitudinal direction of each convex portion 62.

On the other hand, by providing the concave portions 64 and 64 on the lower surface 63 of the translucent member 61, melted transparent adhesive is caused to easily flow farther outside than the concave portion 64. Note that, also in this case, the bump 17 is preferably formed in a manner which allows the upper surface 21 of the bump 17 to become higher than the surface 22 of the transparent adhesive 20.

### Fourth Embodiment

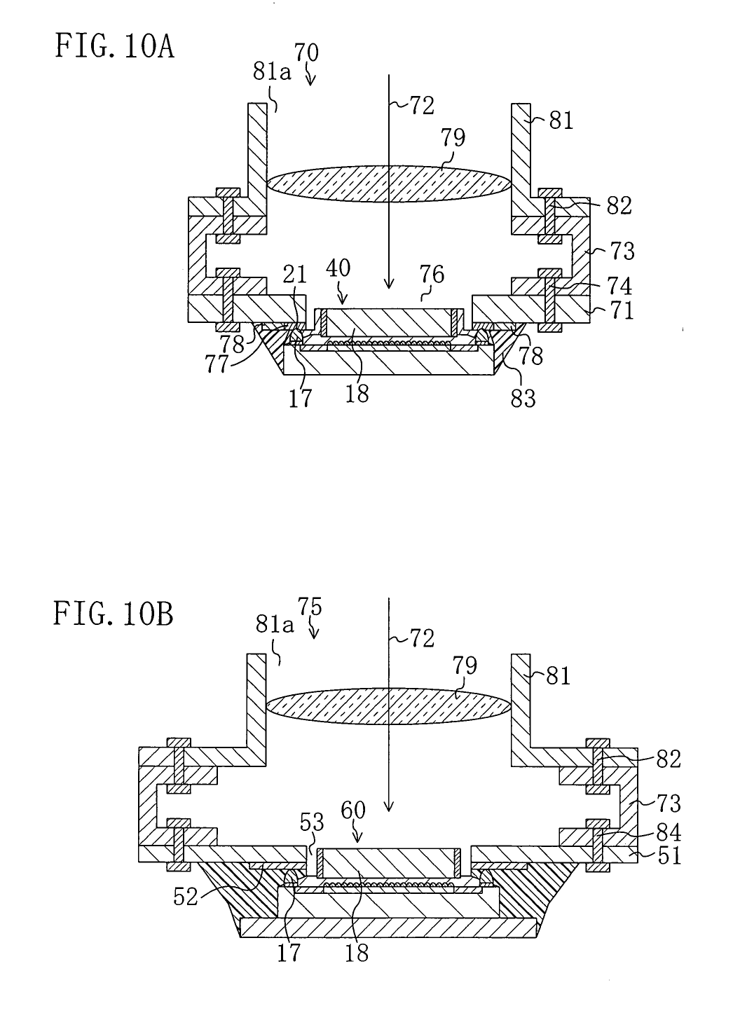

In a fourth embodiment, a semiconductor imaging module will be described. FIG. 10A is a cross-sectional view showing a first semiconductor imaging module 70 according to this embodiment. FIG. 10B is a cross-sectional view showing a second semiconductor imaging module 75 according to this embodiment.

As shown in FIG. 10A, the first semiconductor imaging module 70 comprises the semiconductor image sensor die 40 according to the variation of the first embodiment, a mounting substrate 71, a pedestal 73, and a lens pedestal 81. The semiconductor image sensor die 40 is sealed with a sealing resin 83 and is fixed via the sealing resin 83 to the mounting substrate 71. A through hole (first through hole) 76 is formed in the mounting substrate 71. An electrode terminal 77 and wiring 78 are provided on the mounting substrate 71. The translucent member 18 of the semiconductor image sensor die 40 is housed in the through hole 76. The electrode terminal 77 is provided, surrounding an opening of the through hole 76. The upper surface 21 of the bump 17 of the semiconductor image sensor die 40 contacts the electrode terminal 77. Thereby, the semiconductor image sensor die 40 is electrically connected to the mounting substrate 71. The wiring 78 is provided, surrounding the electrode terminal 77, and is connected to the electrode terminal 77. An external voltage is applied to the wiring 78. Thereby, the external voltage is applied via the wiring 78, the electrode terminal 77, and the bump 17 to the semiconductor image sensor die 40.

The pedestal 73 is fixed via a fixing member 74 to the mounting substrate 71. The lens pedestal 81 is fixed via a fixing member 82 to the pedestal 73. A through hole (second through hole) 81a is formed in the lens pedestal 81. The through hole 81a preferably has an opening larger than the opening of the through hole 76. The through hole 81a holds a lens 79.

In the first semiconductor imaging module 70, by causing the electrode terminal 77 of the mounting substrate 71 to contact the upper surface 21 of the bump 17 of the semiconductor image sensor die 40, the semiconductor image sensor die 40 can be electrically connected to the mounting substrate 71. Therefore, the thickness of the first semiconductor imaging module 70 can be reduced in an optical axis direction of incident light 72.

As shown in FIG. 10B, the second semiconductor imaging module 75 comprises the semiconductor image sensor device 60 of the second embodiment, the pedestal 73, and the lens pedestal 81. Also in the second semiconductor imaging module 75, by causing the bump 17 to contact the electrode terminal 52 of the mounting substrate 51, the semiconductor image sensor device 60 can be produced, so that the thickness of the second semiconductor imaging module 75 can be reduced in the optical axis direction of incident light 72.

### Fifth Embodiment

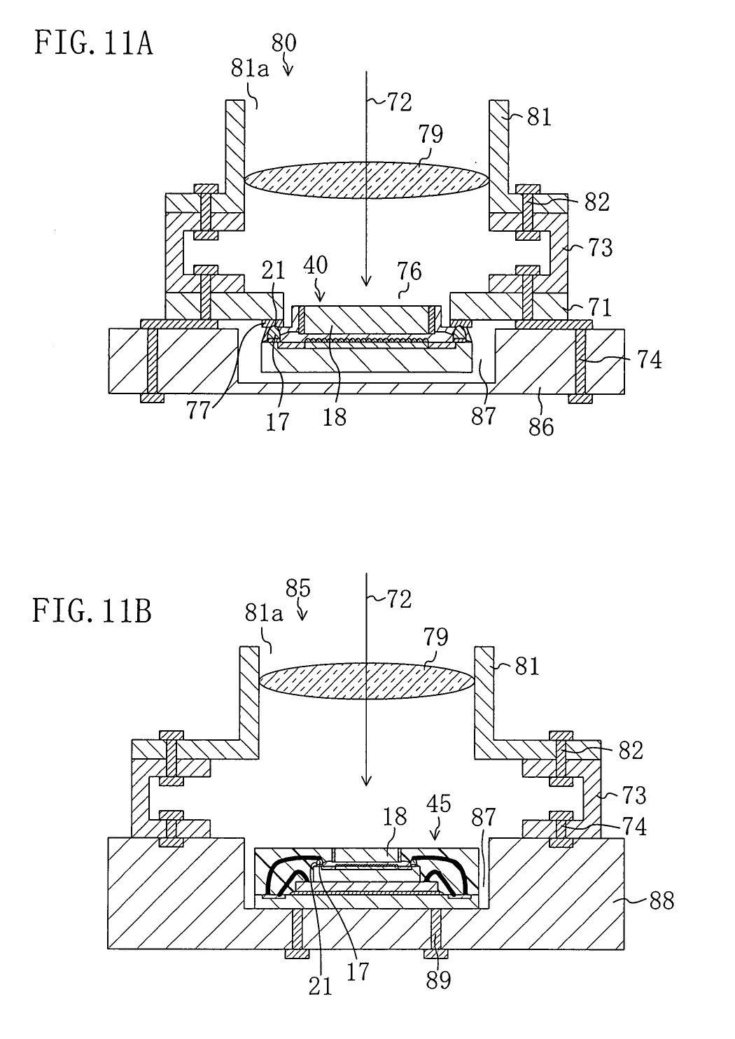

Also in a fifth embodiment, a configuration of a semiconductor imaging module will be described. FIG. 11A is a cross-sectional view showing a first semiconductor imaging module according to this embodiment. FIG. 11B is a cross-sectional view showing a second semiconductor imaging module according to this embodiment.

Although the first semiconductor imaging module 80 of this embodiment has a configuration similar to that of the first semiconductor imaging module 70 of the fourth embodiment, except that a second mounting substrate 86 is provided. The second mounting substrate 86 is fixed via the fixing member 74 to the mounting substrate 71. A concave housing section 87 is formed in an upper surface of the second mounting substrate 86. The semiconductor image sensor die 40 is housed in the housing section 87. Thereby, undesired light can be prevented from entering the semiconductor image sensor die 40 (particularly, the imaging area 13) from the outside of the semiconductor imaging module 80.

The second semiconductor imaging module 85 of this embodiment has a configuration similar to that of the second semiconductor imaging module 75 of the fourth embodiment, except that a third mounting substrate 88 is provided. The third mounting substrate 88 is fixed via the fixing member 74 to the pedestal 73. A concave housing section 87 is formed in an upper surface of the third mounting substrate 88. Wiring 89 is formed, extending from a lower surface of the third mounting substrate 88 to a bottom surface of the housing section 87. Thereby, undesired light can be prevented from entering the semiconductor image sensor device 45 (particularly, the imaging area 13) from the outside of the semiconductor imaging module 85.

### Sixth Embodiment

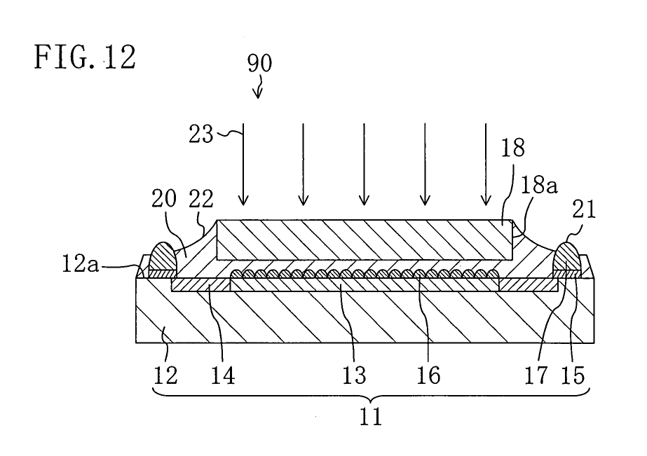

In a sixth embodiment, a configuration of a semiconductor image sensor die will be described. FIG. 12 is a cross-sectional view illustrating a configuration of a semiconductor image sensor die 90 according to this embodiment.

The semiconductor image sensor die 90 of this embodiment is different from the semiconductor image sensor die 10 of the first embodiment in that a side surface 18a of an optical element 18 is covered with the transparent adhesive 20 instead of providing a light shielding member. In such a case, if the upper surface 21 of the bump 17 is located higher than the surface 22 of the transparent adhesive 20 provided on the peripheral circuit area 14, the semiconductor image sensor die 90 of this embodiment exhibits substantially the same effect as that of the semiconductor image sensor die 10 of the first embodiment.

The semiconductor image sensor die 90 of this embodiment can be produced by substantially the same method as that for the semiconductor image sensor die 10 of the first embodiment. Note that, when the translucent member 18 is adhered, an adhesion preventing film is preferably formed on the upper surface of the translucent member 18 so as to prevent the transparent adhesive 20 from adhering to the upper surface of the translucent member 18.

Note that, though not shown in the drawings, the semiconductor image sensor die 90 of this embodiment may be used to produce the semiconductor image sensor device of FIG. 4 or 8 or the semiconductor imaging module of FIG. 10 or 11.

What is claimed is:

1. A semiconductor image sensor die comprising:
a substrate;
an imaging area provided in a portion of an upper surface of the substrate;
a surrounding circuit area provided outside the imaging area of the upper surface of the substrate;
a plurality of electrode portions provided outside the surrounding circuit area of the upper surface of the substrate;
a translucent member provided above the imaging area, covering at least the imaging area;
a transparent adhesive provided on the imaging area and the surrounding circuit area, and for adhering the translucent member to the substrate; and
a bump provided on at least one of the electrode portions,
wherein a surface of the bump includes an upper surface provided higher than an upper surface of the transparent adhesive provided on the surrounding circuit area.

2. A semiconductor image sensor die comprising:
a substrate;
an imaging area provided in a portion of an upper surface of the substrate;
a surrounding circuit area provided outside the imaging area of the upper surface of the substrate;
a plurality of electrode portions provided outside the surrounding circuit area of the upper surface of the substrate;
a translucent member provided above the imaging area, covering at least the imaging area;
a transparent adhesive provided on the imaging area and the surrounding circuit area, and for adhering the translucent member to the substrate; and
a bump provided on at least one of the electrode portions,
wherein the transparent adhesive covers a side surface of the translucent member, and an upper surface of the transparent adhesive becomes closer to the substrate at a point farther away from the translucent member, and
a surface of the bump includes an upper surface exposed from the transparent adhesive provided on the surrounding circuit area.

3. The semiconductor image sensor die of claim 1, wherein the upper surface of the bump is even.

4. The semiconductor image sensor die of claim 1, further comprising:
a microlens provided on the imaging area,
wherein the translucent member is adhered via the transparent adhesive to the microlens.

5. The semiconductor image sensor die of claim 1, wherein
the translucent member has a lower surface in the shape of a polygon, and
a convex portion is provided along at least one side of the polygon.

6. The semiconductor image sensor die of claim 5, wherein each of the electrode portions is provided in an area opposite to the imaging area across the convex portion.

7. The semiconductor image sensor die of claim 1, wherein
the translucent member has a lower surface in the shape of a polygon, and a concave portion is provided along at least one side of the polygon, and
the electrode portion is provided in an area opposite to the imaging area across a side of the polygons other than the side along which the concave portion is formed.

8. The semiconductor image sensor die of claim 1, wherein a light shielding member is provided, covering a side surface of the translucent member and the upper surface of the transparent adhesive provided on the surrounding circuit area while exposing the upper surface of the bump.

9. A semiconductor image sensor die comprising:
the semiconductor image sensor die of claim 1; and
a second semiconductor image sensor die having a major surface on which the semiconductor image sensor die is provided.

10. An optical device element comprising:
a substrate;
a light receiving and emitting area provided in a portion of an upper surface of the substrate;
a surrounding circuit area provided outside the light receiving and emitting area of the upper surface of the substrate;
a plurality of electrode portions provided outside the surrounding circuit area of the upper surface of the substrate;
a translucent member provided above the light receiving and emitting area, covering at least the light receiving and emitting area;
a transparent adhesive provided on the light receiving and emitting area and the surrounding circuit area, and for adhering the translucent member to the substrate; and
a bump provided on at least one of the electrode portions,
wherein a surface of the bump includes an upper surface provided higher than an upper surface of the transparent adhesive provided on the surrounding circuit area.

11. An optical device element comprising:
a substrate;
a light receiving and emitting area provided in a portion of an upper surface of the substrate;
a surrounding circuit area provided outside the light receiving and emitting area, of the upper surface of the substrate;
a plurality of electrode portions provided outside the surrounding circuit area, of the upper surface of the substrate;
a translucent member provided above the light receiving and emitting area, covering at least the light receiving and emitting area;
a transparent adhesive provided on the light receiving and emitting area and the surrounding circuit area, and for adhering the translucent member to the substrate; and
a bump provided on at least one of the electrode portions,
wherein the transparent adhesive covers a side surface of the translucent member, and an upper surface of the transparent adhesive becomes closer to the substrate at a point farther away from the translucent member, and
a surface of the bump includes an upper surface exposed from the transparent adhesive provided on the surrounding circuit area.

12. A semiconductor image sensor device comprising:
the semiconductor image sensor die of claim 1;
a package having an electrode terminal and for housing the semiconductor image sensor die; and
a conductive wire for connecting the upper surface of the bump of the semiconductor image sensor die and the electrode terminal.

13. The semiconductor image sensor device of claim 12, wherein a start end of the conductive wire is connected to the electrode terminal while a terminal end of the conductive wire is connected to the upper surface of the bump.

14. A semiconductor image sensor device comprising:
the semiconductor image sensor die of claim 1;
a flexible mounting substrate having a surface on which the semiconductor image sensor die is provided; and
a sealing resin for sealing the semiconductor image sensor die,
wherein a through hole penetrating in a thickness direction of the flexible mounting substrate is formed in the flexible mounting substrate, and a plurality of electrode terminals are provided on another surface of the flexible mounting substrate, surrounding an opening of the through hole,
the translucent member of the semiconductor image sensor die is plugged in the opening of the through hole, and
the upper surface of the bump of the semiconductor image sensor die is connected to the electrode terminal.

15. A semiconductor imaging module comprising:
the semiconductor image sensor die of claim 1;
a flexible mounting substrate having a surface on which the semiconductor image sensor die is provided; and
a pedestal fixed to the flexible mounting substrate,
wherein a first through hole penetrating in a thickness direction of the flexible mounting substrate is formed in the flexible mounting substrate, and a plurality of electrode terminals are provided on another surface of the flexible mounting substrate, surrounding an opening of the first through hole,
the translucent member of the semiconductor image sensor die is plugged in the opening of the first through hole,
the upper surface of the bump of the semiconductor image sensor die is connected to the electrode terminal,
a second through hole is formed in the pedestal, communicating with the first through hole, and
the second through hole has an opening larger than the opening of the first through hole.

16. An optical device module comprising:
the optical device element of claim 10;
a flexible mounting substrate having a surface on which the optical device element is provided; and
a pedestal fixed to the flexible mounting substrate,
wherein a first through hole penetrating in a thickness direction of the flexible mounting substrate is formed in the flexible mounting substrate, and a plurality of electrode terminals are provided on another surface of the flexible mounting substrate, surrounding an opening of the first through hole,
the translucent member of the optical device element is plugged in the opening of the first through hole,
the upper surface of the bump of the optical device element is connected to the electrode terminal,
a second through hole is formed in the pedestal, communicating with the first through hole, and
the second through hole has an opening larger than the opening of the first through hole.

17. A method for producing a semiconductor image sensor die, comprising the steps of:
preparing a substrate, wherein the substrate comprises an imaging area provided in a portion of a surface of the substrate, a surrounding circuit area provided outside the imaging area of the surface of the substrate, a plurality of electrode portions provided outside the surrounding circuit area of the surface of the substrate, and a bump provided on at least one of the electrode portions;
providing a transparent adhesive onto at least the imaging area and the surrounding circuit area; and
adhering a translucent member onto an upper surface of the transparent adhesive, covering the imaging area,
wherein, in the providing step, the transparent adhesive is provided in a manner which allows an upper surface of the bump to be exposed.

18. The method of claim 17, further comprising:
providing a light shielding member on a side surface of the translucent member and a surface of the transparent adhesive provided on the surrounding circuit area, after the adhering step.

19. A method for producing a semiconductor image sensor die, comprising the steps of:
preparing a substrate, wherein the substrate comprises an imaging area provided in a portion of a surface of the substrate, a surrounding circuit area provided outside the imaging area of the surface of the substrate, a plurality of electrode portions provided outside the surrounding circuit area of the surface of the substrate, and a bump provided on at least one of the electrode portions;
providing a transparent adhesive onto at least the imaging area and the surrounding circuit area; and
adhering a translucent member onto an upper surface of the translucent member, covering the imaging area,
wherein, in the providing step, the transparent adhesive is provided in a manner which allows a side surface of the translucent member to be covered and an upper surface of the bump to be exposed.

20. The method of claim 17, further comprising:
causing the upper surface of the bump to be even.
